(19) United States
(12) Patent Application Publication
(10) Pub. No.: US 2014/0084762 A1
(43) Pub. Date: Mar. 27, 2014

(54) ELECTRONIC DEVICE AND FASTENING APPARATUS THEREOF

(71) Applicants: INVENTEC (PUDONG) TECHNOLOGY CORPORATION, Shanghai (CN); INVENTEC CORPORATION, Taipei (TW)

(72) Inventor: Chien-Hua Lai, Taipei (TW)

(73) Assignees: INVENTEC CORPORATION, Taipei (TW); INVENTEC (PUDONG) TECHNOLOGY CORPORATION, Shanghai (CN)

(21) Appl. No.: 13/783,602

(22) Filed: Mar. 4, 2013

(30) Foreign Application Priority Data
Sep. 25, 2012 (CN) 201210362136.8

(51) Int. Cl. H05K 5/02; H05K 5/00

(52) U.S. Cl. CPC H05K 5/0221; H05K 5/0004
USPC 312/223.1; 403/326; 403/327

(57) ABSTRACT

A fastening apparatus, applicable for adjusting a fastening state of a first object and a second object by a first magnetic component, includes a first fastening component, an elastic component, a second fastening component and a second magnetic component. The first fastening component is disposed on the first object. The elastic component includes a first end disposed on the second object and a second end connected to the second fastening component. The second magnetic component is disposed on the second fastening component. The first magnetic component attracts the second magnetic component to move the second fastening component between a first position and a second position. When the second fastening component is at the first position, the first object is affixed to the second object. When the second fastening component is at the second position, the first object is separated from the second object.

### CROSS-REFERENCE TO RELATED APPLICATIONS

This non-provisional application claims priority under 35 U.S.C. §119(a) on Patent Application No(s). 201210362136.8 filed in China on Sep. 25, 2012, the entire contents of which are hereby incorporated by reference.

### BACKGROUND OF THE INVENTION

1. Technical Field of the Invention

The disclosure relates to a fastening apparatus, and more particularly to a fastening apparatus assembled by a magnetic force.

2. Description of the Related Art

Courtesy of the advances in semiconductor and display technology, electronic devices are developed towards being compact, multi-functional and having a portable design. The common electronic devices are, for example, smart phones, tablet computers or laptop computers. In order to make the electronic devices to be able to be carried conveniently, lighter and humanized, conventional input apparatuses, such as keyboards or mice, are replaced by touch panels.

Typically, take a touch panel for example, the touch panel is generally assembled on a second casing, and the second casing surrounds the touch panel according to design requirements. When the first casing and the second casing are separated from each other because the electronic device needs to be repaired, the touch panel needs to be taken off from the second casing in advance. However, when the touch panel are disassembled at times, the exterior of the casing is easily scratched or damaged because the tool or applying forces are improper, thereby increasing the fixing cost.

### SUMMARY OF THE INVENTION

An embodiment of the disclosure provides a fastening apparatus, applicable for adjusting a fastening state of a first object and a second object by a first magnetic component. The fastening apparatus comprises a first fastening component, an elastic component, a second fastening component and a second magnetic component. The first fastening component is disposed on the first object. The elastic component includes a first end and a second end opposite to each other. The first end is disposed on the second object. The second fastening component is connected to the second end of the elastic component. The second magnetic component is disposed on the second fastening component. The first magnetic component is adapted for attracting the second magnetic component to move the second fastening component between a first position and a second position. When the second fastening component is at the first position, a structural interference is formed between the second fastening component and the first fastening component, such that the first object is affixed to the second object. When the second fastening component is at the second position, the second fastening component is released from the first fastening component, and the first object is separated from the second object.

Another embodiment of the disclosure provides an electronic device comprising a first casing, a second casing and a fastening apparatus. The second casing is adapted for being connected to the first casing. The fastening apparatus is adapted for adjusting a fastening state of a first casing and a second casing by a first magnetic component. The fastening apparatus comprises a first fastening component, an elastic component, a second fastening component and a second magnetic component. The first fastening component is disposed on the second casing. The elastic component includes a first end and a second end opposite to each other. The first end is disposed on the first casing. The second fastening component is connected to the second end of the elastic component. The second magnetic component is disposed on the second fastening component. The first magnetic component is adapted for attracting the second magnetic component to move the second fastening component between a first position and a second position. When the second fastening component is at the first position, a structural interference is formed between the second fastening component and the first fastening component, such that the second casing is affixed to the first casing. When the second fastening component is at the second position, the second fastening component is released from the first fastening component, and the second casing is separated from the first casing.

### BRIEF DESCRIPTION OF THE DRAWINGS

The disclosure will become more fully understood from the detailed description given herein below for illustration only, thus does not limit the disclosure, wherein:

FIG. 1A is a perspective view of an electronic device according to an embodiment of the disclosure;

FIG. 1B is a cross-sectional view of the electronic device along a line A-A in FIG. 1A;

FIG. 1C is a schematic view of the electronic device removing a touch panel in FIG. 1A;

FIG. 2A is a schematic view of a second fastening component of the electronic device rotating in FIG. 1B;

FIG. 2B is a schematic view of the electronic device in FIG. 1B; and

FIGS. 3A to 3C are process flow views of the electronic device in FIG. 1A when a second casing is assembled to a first casing.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

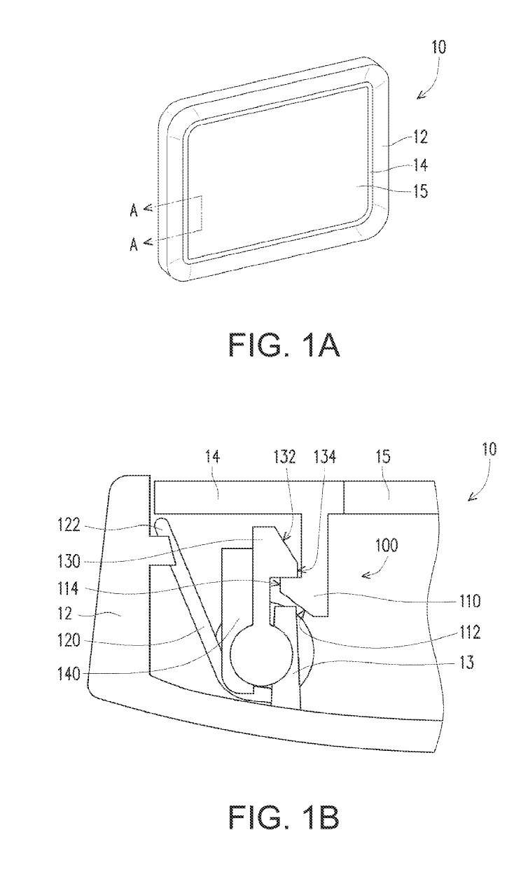

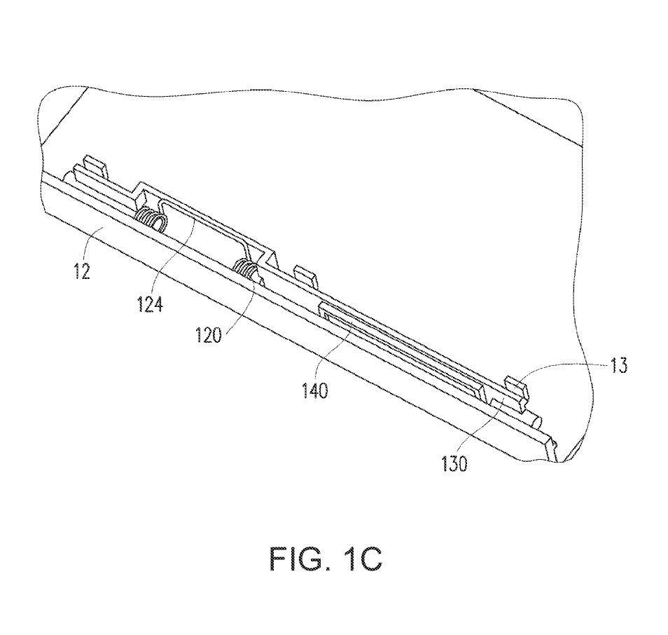

Please refer to FIGS. 1A, 1B and 1C together, FIG. 1A is a perspective view of an electronic device according to an embodiment of the disclosure, FIG. 1B is a cross-sectional view of the electronic device along a line A-A in FIG. 1A, and FIG. 1C is a schematic view of the electronic device removing a touch panel in FIG. 1A. In this embodiment, an electronic device 10 comprises a first casing 12 (i.e., second object), a second casing 14 (i.e., first object) and a fastening apparatus 100. In this embodiment, for example, the electronic device 10 is a tablet computer, the first casing 12 is a main body of the tablet computer, the second casing 14 is a front frame of the tablet computer, and the second casing 14 is adapted for loading with a touch panel 15. The second casing 14 is connected to the first casing 12. The fastening apparatus 100 comprises a first fastening component 110, an elastic component 120, a second fastening component 130 and a second magnetic component 140. The first fastening component 110 is disposed on the second casing 14. The elastic component 120 includes a first end 122 and a second end 124 opposite to each other. The first end 122 is disposed on the first casing 12. The second fastening component 130 is connected to the second end 124 of the elastic component 120. As shown in FIG. 1C, in order to clearly describe the disposing relationships between the elastic component 120, the second fastening component 130 and the first casing 12, some unnecessary components of the electronic device 10 are omitted. The second fastening component 130, disposed on the first casing 12, is adapted for rotating in relative to the first casing 12. The second magnetic component 140 is disposed on the second fastening component 130. The second fastening component 130 is adapted for being driven by the magnetic force from the second magnetic component 140 so as to rotate in relative to the first casing 12.

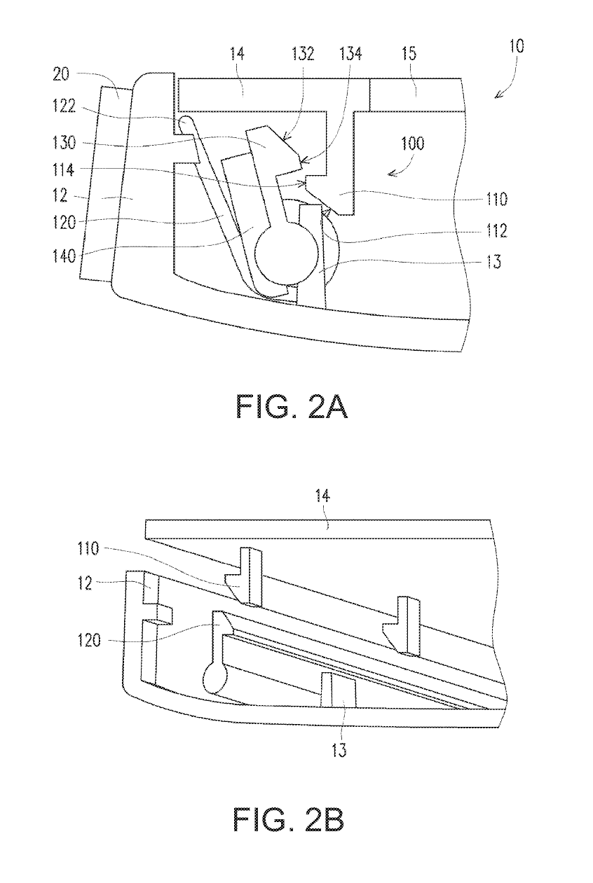

Please continuously refer to FIG. 1B, 1C and 2A, and FIG. 2A is a schematic view of a second fastening component of the electronic device rotating in FIG. 1B. In this embodiment, the first magnetic component 20 is adapted for attracting the second magnetic component 140 so as to move the second fastening component 130 between a first position (as shown in FIG. 1B) and a second position (FIG. 2A), thereby adjusting the fastening state of the second casing 14 and the first casing 12. When the second fastening component 130 is at the first position, a structural interference is formed between the second fastening component 130 and the first fastening component 110, such that the second casing 14 is affixed to the first casing 12. When the second fastening component 130 is at the second position, the second fastening component 130 is released from the first fastening component 110 (the fastening between the second fastening component 130 and the first fastening component 110 is released), the second casing 14 is separated from the first casing 12.

In order to describe the motion of the fastening apparatus 100 in FIGS. 1B and 2A, in FIG. 1B, the second fastening component 130 stays at the first position and forms the structural interference with the first fastening component 110. During the repairing process of the electronic device 10, the second casing 14 needs to be separated from the first casing 12, by means of moving the first magnetic component 20 towards the electronic device 10, the first magnetic component 20 and the second magnetic component 140 are attracted with each other. The second magnetic component 140 may drive the second fastening component 130 to move to the second position in relative to the first casing 12, as shown in FIG. 2A, thereby releasing the structural interference of the second fastening component 130 and the first fastening component 110.

In this embodiment, the second fastening component 130 is pivoted to the first casing 12, which is beneficial for the second fastening component 130 to rotate between the first position and the second position. When the second fastening component 130 is at the second position, the elastic potential energy of the elastic component 120 is greater than the elastic potential energy of the elastic component 120 when the second fastening component 130 is at the first position. Typically, the above-mentioned elastic component 120 is a torsion spring. The torsion spring is respectively connected to the first casing 12 and the second fastening component 130, which is regarded as a driving force of restoring position of the second fastening component 130. However, the type of the elastic component 120 is not limited to the disclosure.

When the second casing 14 needs to be assembled with the first casing 12 again, by means of moving the first magnetic component 20 towards the second magnetic component 140, the second fastening component 130 is rotated to the second position, as shown in FIG. 2A. At this time, the elastic component 120 stores the elastic potential energy. Then, the second casing 14 needs to be assembled back to the first casing 12, and after the second casing 14 is assembled with the first casing 12, the first magnetic component 20 is removed away from the electronic device 10. The second magnetic component 140 is not attracted by the magnetic force of the first magnetic component 20, the stored elastic potential energy of the elastic component 120 is released to make the second fastening component 130 move to the first position, as shown in FIG. 1B. The above-mentioned description describes only one way of assembling the second casing 14 to the first casing 12, but is not limited to the disclosure. In this embodiment, by means of the first magnetic component 20 and the second magnetic component 140, during the assembly and disassembly processes of the first casing 12 and the second casing 14, the fastening apparatus 100 may prevents the touch pane 115 from damage due to improper force.

Furthermore, in the conventional design of the fastening component, when the height of the curved portion of the hook is longer, the force arm of the hook is longer accordingly, which makes the flexible arm provide better deforming deflection (namely, flexibility). Therefore, during the assembly of the second casing 14 and the first casing 12, the hook provides better flexible deformation, which prevents the hook from permanent deformation, thereby affecting the assembly. However, in this embodiment, the second fastening component 130 is fastened to the first fastening component 110 through the pivot, and therefore, during the assembly of the second casing 14 and the first casing 12, the second fastening component 130 does not need to be fastened to the fastening component 110 by the flexible deformation. Accordingly, the height of the second fastening component 130 may be reduced, such that the thickness of the electronic device 10 which employs the fastening apparatus 100 is reduced.

For example, when the first magnetic component 20 is disposed in a repairing tool (not shown), and the electronic device 10 is adapted for being contained in the repairing tool. When the electronic device 10 is disposed in the repairing tool, the first magnetic component 20 is in the vicinity of the electronic device 10 and close to the second magnetic component 140, which is beneficial for repair and assembly. However, the structure and disposing position of the first magnetic component 20 do not limit the disclosure.

In this embodiment, the second fastening component 130 is attracted to the first magnetic component 20 by the second magnetic component 140. The second magnetic component 140 comprises a metal or a magnet. In other words, for example, the second fastening component 130 is a hook made of plastic and made by injection molding, and a magnet is embedded in the second fastening component 130. Thus, when the first magnetic component 20 (as shown in FIG. 2A) is moved towards the electronic device 10, the second fastening component 130 is attracted by the first magnetic component 20 rotate. In other embodiments which are not shown in the drawings, the second fastening component is made form a metal which is magnetically attracted by other magnets. The materials and the combination of the second fastening component and the second magnetic component do not limit the disclosure.

Please refer to FIG. 2B, which is a schematic view of the electronic device in FIG. 1B. In order to clearly describe the structure of the second fastening component 130, some unnecessary components of the electronic device 10 are omitted. The first casing 12 includes block portion 13. When the second fastening component 130 is restored (i.e., moved back) to the first position, the block portion 13 is adapted for limit the second fastening component 130 to stay at the first position. In other words, the block portion 13 may prevent the second fastening component 130 from being pushed over the first position after the elastic component 120 has released its elastic potential energy, thereby solving the problem that when the second casing 14 is assembled to the first casing 12 casing again, the first fastening component 110 may not fasten to the second fastening component 130 again.

In this embodiment, the method for assembling the second casing 14 back to the first casing 12 may be applied by the above-mentioned manner. That is to say, the first magnetic component 20 is moved towards the second magnetic component 140 to make the second fastening component 130 move to the second position, as shown in FIG. 2A. Then, the second casing 14 is assembled to the first casing 12 again. However, the assembly method is not limited to the disclosure. Another method for assembly is described as follows.

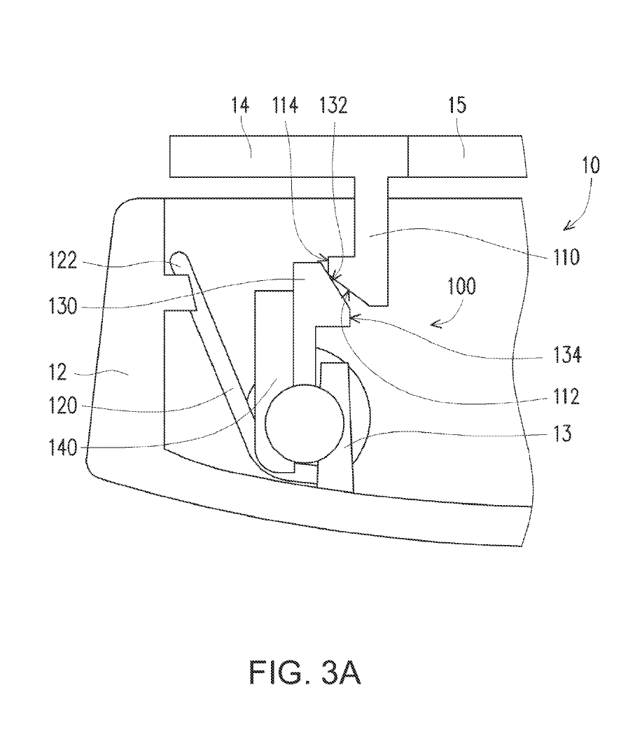

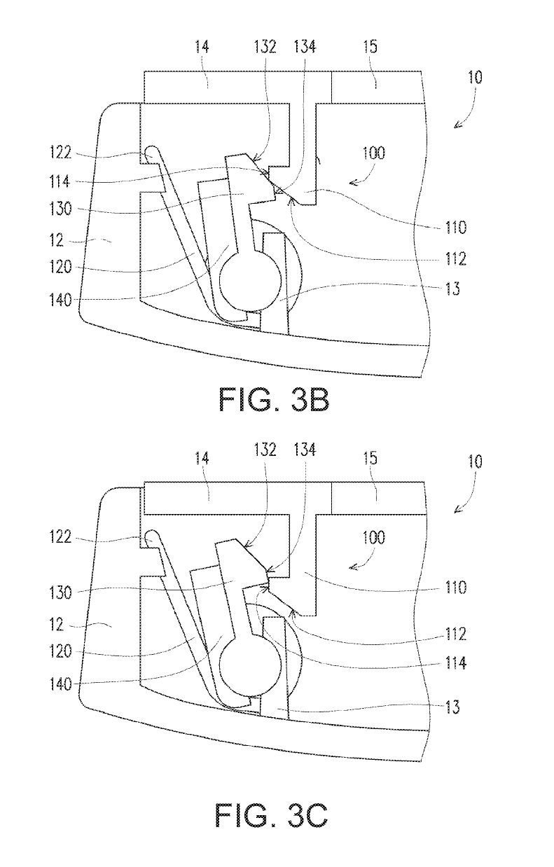

Please refer to FIGS. 3A to 3C, which are process flow views of the electronic device in FIG. 1A when a second casing is assembled to a first casing. In this embodiment, the first fastening component 110 includes a first slope 112. The second fastening component 130 includes a second slope 132. During the process of assembling the second casing 14 to the first casing 12, the first slope 112 is moved along the second slope 132 to make the second fastening component 130 rotate from the first position to the second position. Typically, when the second casing 14 is assembled back to the first casing 12, the first fastening component 110, disposed on the second casing 14, is in contact with the second fastening component 130 at the first position (as shown in FIG. 3A). Referring to FIG. 3B, the first slope 112 of the first fastening component 110 abuts against the second slope 132 of the second fastening component 130, such that the first slope 112 pushes the second slope 132 to drive the second fastening component 130 to rotate in relative to the first casing 12, until the second fastening component 130 reaches the second position (FIG. 3C).

During the rotation of the second fastening component 130 (as shown in FIGS. 3B and 3C), the flexible component 120 stores the elastic potential energy. After the first slope 112 is removed from the second slope 132, the first fastening component 110 has no interference with other components on the assembling path of the first fastening component 110 (i.e., the path on which the first fastening component 110 moves). A head portion 134 of the second fastening component 130 abuts against a head portion 114 of the first fastening component 110, until the second casing 14 is assembled back to the first casing 12, and the head portion 114 of the first fastening component 110 does not abut against the head portion 134 of the second fastening component 130. The second fastening component 130 is returned to the first position by releasing the elastic potential energy of the flexible component 120. Therefore, the structural interference is formed, as shown in FIG. 1B.

To sum up, in the electronic device according to the disclosure, by means of the second magnetic component and the first magnetic component attracting to each other, the fastening apparatus makes the second fastening component move between the first position and the second position, thereby adjusting the fastening state of the second casing and the first casing. When the second fastening component is at the first position, the structure interference is formed between the second fastening component and the first fastening component. When the second fastening component is at the second position, the second fastening component is released from the first fastening component. Therefore, according to the disclosure, the fastening apparatus may prevent the components in the electronic device from damage because of improper applying force when the second casing is disassembled form the first casing. Moreover, the second fastening component is affixed (namely, fastened) to the first fastening component by pivoting, and the second fastening component does not need a longer flexible arm, such that the height of the second fastening component may be reduced, and the thickness of the electronic device employing the fastening apparatus may also be reduced. Moreover, the first casing of the electronic device comprises the block portion. When the second casing is disassembled from the first casing, and the second fastening component is restored (namely, returned) from the second position, the block portion may limit the second fastening component to stay at the first position, which is beneficial for the following assembly.

What is claimed is:

1. A fastening apparatus, applicable for adjusting a fastening state of a first object and a second object by a first magnetic component, the fastening apparatus comprising:
a first fastening component disposed on the first object;
an elastic component including a first end and a second end opposite to each other, and the first end disposed on the second object;
a second fastening component connected to the second end of the elastic component; and
a second magnetic component disposed on the second fastening component, the first magnetic component being adapted for attracting the second magnetic component to move the second fastening component between a first position and a second position, wherein, when the second fastening component is at the first position, a structural interference is formed between the second fastening component and the first fastening component, and the first object is affixed to the second object;
wherein, when the second fastening component is at the second position, the second fastening component is released from the first fastening component, and the first object is separated from the second object.

2. The fastening apparatus according to claim 1, wherein the second fastening component is pivoted to the second object such that the second fastening component is adapted for rotating between the first position and the second position, and when the second fastening component is at the second position, the elastic potential energy of the elastic component is greater than the elastic potential energy of the elastic component when the second fastening component is at the first position.

3. The fastening apparatus according to claim 1, wherein the second object comprises a block portion, when the second fastening component is moved from the second position to the first position, the block portion is adapted for limiting the second fastening component to stay at the first position.

4. The fastening apparatus according to claim 1, wherein the elastic component is a torsion spring, and the second magnetic component comprises a metal or a magnet.

5. The fastening apparatus according to claim 4, wherein the first fastening component includes a first slope, the second fastening component includes a second slope, and when the first object is assembled to the second object, the first slope is moved along the second slope to rotate the second fastening component from the first position to the second position.

6. An electronic device, comprising:
a first casing;
a second casing adapted for being connected to the first casing; and
a fastening apparatus adapted for adjusting a fastening state of a first casing and a second casing by a first magnetic component, the fastening apparatus comprising:
a first fastening component disposed on the second casing;
an elastic component including a first end and a second end opposite to each other, and the first end disposed on the first casing;
a second fastening component connected to the second end of the elastic component; and
a second magnetic component disposed on the second fastening component, the first magnetic component being adapted for attracting the second magnetic component to move the second fastening component between a first position and a second position, wherein, when the second fastening component is at the first position, a structural interference is formed between the second fastening component and the first fastening component, and the second casing is affixed to the first casing;
wherein, when the second fastening component is at the second position, the second fastening component is released from the first fastening component, and the second casing is separated from the first casing.

7. The fastening apparatus according to claim 6, wherein the second fastening component is pivoted to the first casing such that the second fastening component is adapted for rotating between the first position and the second position, and when the second fastening component is at the second position, the elastic potential energy of the elastic component is greater than the elastic potential energy of the elastic component when the second fastening component is at the first position.

8. The fastening apparatus according to claim 6, wherein the first casing comprises a block portion, and when the second fastening component is moved from the second position to the first position, the block portion is adapted for limiting the second fastening component to stay at the first position.

9. The fastening apparatus according to claim 6, wherein the elastic component is a torsion spring, and the second magnetic component includes a metal or a magnet.

10. The fastening apparatus according to claim 9, wherein the first fastening component comprises a first slope, the second fastening component comprises a second slope, and when the second casing is assembled to the first casing, the first slope is moved along the second slope to rotate the second fastening component from the first position to the second position.
